(19) United States
(12) Patent Application Publication
(10) Pub. No.: US 2004/0090229 A1
(43) Pub. Date: May 13, 2004

(54) IC chip for a compact, low noise magnetic impedance sensor

(76) Inventor: Takeshi Kimura, Kanagawa (JP)

Correspondence Address: Ivan S. Kavrukov, Esq., Cooper & Dunham LLP, 1185 Avenue of the Americas, New York, NY, 10036, US

(21) Appl. No.: 10/694,668

(22) Filed: Oct. 27, 2003

(30) Foreign Application Priority Data
Oct. 31, 2002 (JP) 2002-318249

(51) Int. Cl. G01R 33/00; G01R 33/04

(52) U.S. Cl. 324/253; 360/111

(57) ABSTRACT

An IC chip for a magnetic impedance (MI) sensor includes an MI element electrode, a switch unit, and a power supply electrode, wherein the MI element electrode is disposed in the neighborhood of a first side face of the IC chip, and the power supply electrode is disposed in the neighborhood of a second side face opposite the first side face. A power supply voltage is provided to the switch unit through the power supply electrode, and a high frequency pulse exciting current is provided to the MI element through the MI element electrode. Since the first power supply electrode and the MI element electrode are disposed at a distance, noise generated by the high frequency pulse exciting current is prevented from superposing the signals of circuits other than the switch unit.

### BACKGROUND OF THE INVENTION

1. Field of the Invention

The present invention generally relates to a magnetic impedance sensor, and more particularly, to an integrated circuit chip built into a compact, low noise magnetic impedance sensor provided with a magnetic impedance element that can detect a weak magnetic field. The present invention further relates to an electronic apparatus in which the magnetic impedance sensor is provided.

2. Description of the Related Art

Magneto resistive (MR) elements, especially Giant Magneto Resistive (GMR) elements have been increasing the recording density of magnetic recording apparatuses. The GMR element detects an external magnetic field using a spin electronics effect embodied by a fixed magnetization layer and a free layer that is a soft magnetic layer of which magnetization direction is determined by an external magnetic field. The flow of electrons through the fixed magnetization layer and the free layer depends on the angle between the magnetization of the fixed magnetic layer and the magnetization of the free layer. The GMR elements can be downsized to several tens μm. However, the sensitivity of the GMR elements is about 10 mOe.

Magnetic Impedance (MI) elements may break through the above limit of sensitivity. MI elements are the subject of intense studies. An MI element is provided with an amorphous wire made of soft magnetic material and a detection coil wound on the amorphous wire. A high frequency current or a pulse current is provided to the amorphous wire, and causes skin effect. The impedance of the amorphous wire changes as the magnetic permeability of the amorphous wire changes to an external magnetic field applied in the length direction of the amorphous wire. The detection coil detects the change in the impedance by detecting current induced therein. The sensitivity of the MI elements is about 1 μOe. The MI elements, if driven by a short pulse current, consume low power. The MI elements are used for applications that require high sensitivity and/or low power consumption.

The greater is the pulse current provided to the amorphous wire, the higher is the sensitivity of the MI element. Additionally, the more square is the pulse current provided to the amorphous wire, the higher is the sensitivity of the MI element. However, since the pulse current is a square wave of a relatively large current, it may cause noise in an electronic circuit provided for the MI element. The noise lowers signal to noise ratio of an MI sensor and degrades the sensitivity thereof.

If the electronic circuit is integrated, the integrated circuit (IC) becomes more vulnerable to noise. The noise may affect the IC through radiation of electromagnetic waves and/or through a power line and a ground line of the integrated circuit. The noise may be superposed to a signal output from the IC.

The IC chip may be enlarged in order to reduce the effect of noise. However, the MI sensor cannot be downsized.

### SUMMARY OF THE INVENTION

Accordingly, it is a general object of the present invention to provide a novel and useful MI sensor with which at least one of the above problems is solved.

More particularly, it is an object of the present invention to provide a compact, low noise MI sensor, an IC chip for the MI sensor, and an electronic apparatus in which the MI sensor is provided.

To achieve one or more of the above objects, an IC chip for providing an exciting current to an MI element of an MI sensor, which MI element detects an external magnetic field, according to the present invention, the MI chip includes: an MI element electrode to which the MI element is connected; a switch unit that, in response to a pulse signal, provides the MI element with the exciting current via said MI element electrode; and a first power supply electrode through which said switch unit is provided with electric power; the IC chip having a first side face and a second side face opposite the first side face; wherein said MI element electrode is disposed in a neighborhood of the first side face; and said first power supply electrode is disposed in a neighborhood of the second side face.

Since the exciting current is a series of high frequency pulses, it generates noise in circuits provided in the IC chip through the radiation of electromagnetic wave and/or induction. The MI element electrode through which the exciting current is provided from the switch unit to the MI element is disposed in the neighborhood of the first side face facing the MI element. Additionally, the first power supply electrode through which the power supply voltage is provided from an external power supply to the switch unit is disposed in the neighborhood of the second side face opposite the first side face. Since the MI element electrode and the first power supply electrode are disposed at a distance, the noise is prevented from superposing the signals of circuits connected to the first power supply electrode, other than the switch unit. Accordingly, the signal to noise ratio of the MI sensor is improved.

Other objects, features, and advantages of the present invention will become more apparent from the following detailed description when read in conjunction with the accompanying drawings.

### BRIEF DESCRIPTION OF THE DRAWINGS

FIG. 1 is a perspective view showing an MI sensor according to a first embodiment;

FIG. 2 is a perspective view showing an MI element according to the first embodiment;

FIG. 3 is a circuit diagram showing an MI sensor circuit according to the first embodiment;

FIG. 4 shows waveforms of the electronic circuit shown in FIG. 3;

FIG. 5 is a top plan view showing the disposition of the MI element and the circuit blocks of an IC chip according to the first embodiment;

FIG. 6 is a perspective view showing an MI sensor according to a second embodiment;

FIG. 7 is a circuit diagram showing an MI sensor circuit according to the second embodiment;

FIG. 8 is an exploded view of a cellular phone according to a third embodiment; and

FIG. 9 is an enlarged view showing a portion of the cellular phone in which MI sensors according to the third embodiment is disposed.

### DETAILED DESCRIPTION OF THE PREFERRED EMBODIMENTS

The preferred embodiments of the present invention are described in detail with reference to the drawings.

[First Embodiment]

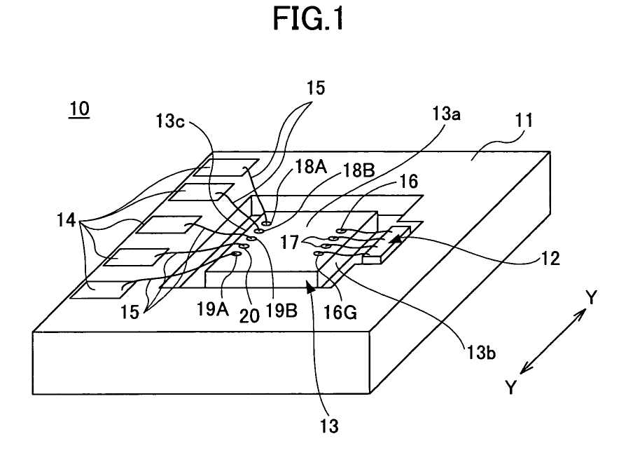

FIG. 1 is a perspective view showing an MI sensor 10 according to a first embodiment of the present invention. As shown in FIG. 1, the MI sensor 10 includes a case 11, a Magnetic Impedance (MI) element 12, and an IC chip 13. The case 11 is made of ceramic, glass, plastic, and silicon, for example. The MI element is disposed in the case 11 in parallel with the principal plane of the case 11. The IC chip 13 is connected to the MI element 12 and disposed in the case 11. The IC chip 13 provides the MI element 12 with exciting current. An external magnetic field induces a signal at the MI element 12. This effect is referred to as a magnetic impedance effect. The IC chip 13 detects and processes the induced signal, and outputs an output signal corresponding to the intensity of the external magnetic field.

A quadrangle recess where the IC chip 13 is disposed is formed at the center of the case 11. Additionally, another recess where the MI element 12 is disposed is formed in the case 11. The recess where the MI element 12 is disposed is about 4 mm long and several millimeters wide. Multiple case electrodes 14 are provided on the top face of the peripheral portion of the case 11. The case electrodes 14 are connected to the IC chip 13 via wires 15. The case electrodes 14 may be further connected with an external device for exchanging signals.

The IC chip 13 may be fabricated by CMOS technology or bipolar technology, for example. The IC chip 13 includes the following electrodes: an exciting current electrode 16, an exciting current ground electrode 16G, and two detected signal electrodes 17. These electrodes are formed on the top face 13a of the IC chip 13 near a first side face 13b facing the MI element 12. The four electrodes 16, 16G, and 17 are used for connecting the IC chip 13 to the MI element 12. Specifically, the exciting current electrode 16 and the exciting current ground electrode 16G are used for providing the exciting current to the MI element 12. The two detected current electrodes 17 are used for detecting the signal induced at the MI element 12.

Additionally, the IC chip 13 includes the following electrodes: power supply electrodes 18A and 18B, ground electrodes 19A and 19B, and an output electrodes 20 formed on the top face 13a of the IC chip 13 near a second side face 13c opposite the first side face 13b. The power supply electrodes 18A and 18B are electrodes through which power is supplied to the IC chip 13. The ground electrodes 19A and 19B are used for ground. The output electrode 20 is used for outputting the output signal to an external CPU, for example.

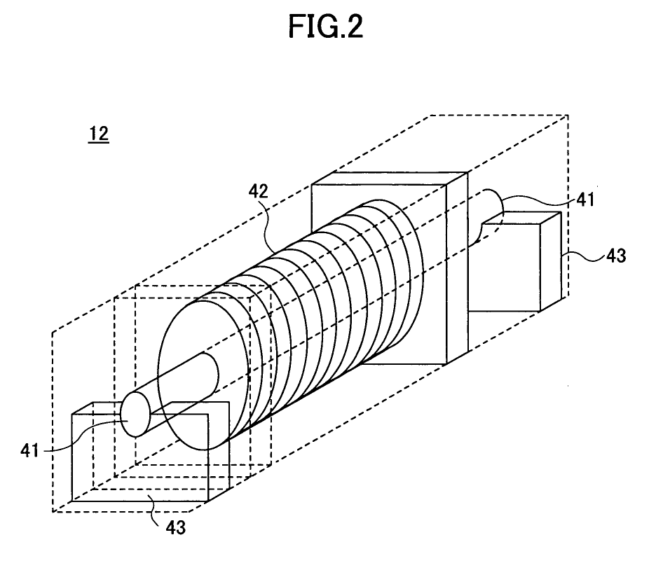

The IC chip 13 transmits a pulse exciting current via the exciting current electrode 16 to an amorphous wire (to be described later with reference to FIG. 2) of the MI element 12. A signal induced at a detection coil 42 (to be described later with reference to FIG. 2) is transmitted to the IC chip 13 via the detected signal electrode 17. The detected signal depends on the intensity of the external magnetic field. The detected signal is converted by an electronic circuit into an output signal indicating the external magnetic field. The electronic circuit is described below.

FIG. 2 is a perspective view showing the MI element 12 of the MI sensor 10 according to a first embodiment of the present invention. The MI element 12 includes the following: an amorphous wire 41, a detection coil 42, and electrodes 43. The detection coil 42 is wound on the amorphous wire 41. The electrodes 43 are electrically connected to the amorphous wire 41. The exciting current is provided through the electrode 43 from the IC chip 13 to the amorphous wire 41. The size of the MI element 12 may be about 4 mm long, 1 mm wide, and 0.3 mm high, for example. The MI element 12 can detect the intensity of an external magnetic field in the length direction of the amorphous wire 41 using, for example, the afore described magnetic impedance effect. That is, the MI sensor 12 shown in FIG. 1 can detect the component of the external magnetic field in the Y direction (see FIG. 1), that is, the length direction of the MI element 12.

In an embodiment, the amorphous wire 41 is about 2 mm long and several tens micrometer in diameter, and is made of soft magnetic amorphous magnetic material such as FeB, CoB, FeNiSiB, FeCoSiB, CoSiB, for example. In order to make the detected signal linear, a magnetic material that shows little or no magnetic distortion under an external magnetic field of several Oe or magnetic material after wire drawing is desired.

The amorphous wire 41 may be replaced with a soft magnetic layer or a soft magnetic thin body. However, the amorphous wire 41 is preferred to the soft magnetic layer and the soft magnetic thin body because the demagnetizing field in the width direction of the amorphous wire 41 is less than that of the soft magnetic layer and the soft magnetic thin body, and the demagnetizing field of the amorphous wire 41 in the circumferential direction is zero.

The amorphous wire 41 may alternatively comprise a non-magnetic wire coated with soft magnetic material of 10 nm-5 μm thickness using an electrodeposition method, an evaporation method, a sputtering method, or a CVD method, for example. As described above, the soft magnetic material may be selected from FeB, CoB, FeNiSiB, FeCoSiB, and CoSiB, for example. The soft magnetic material may alternatively be selected from NiFe (Permalloy) and FeAlSi. The non-magnetic wire may be made of Al or Cu, for example. In some applications, the non-magnetic wire coated with soft magnetic material may be preferable to the amorphous wire since the soft magnetic material can be selected from a wider range of materials and the non-magnetic wire can be selected from a material that is easily connectable to electrodes.

The length of the amorphous wire 41 may be 2 mm or less. It may be even 1 mm or less. Even if the amorphous wire 41 is shortened, the sensitivity of the MI element 12 is not degraded in accordance with the magnetic impedance effect. The MI element 12 and accordingly the MI sensor 10 can be made compact.

When the amorphous wire 41 is shortened, bonding between the amorphous wire 41 and the electrodes 43 made of Aluminum, for example, may become difficult. The bonding between the amorphous wire 41 and the electrodes 43 is possible using, for example, a thermo-compression bonding method combined with supersonic wave. The detection coil 42 wound on the amorphous wire 41 in the circumferential directions is 10 to 30 turns, for example.

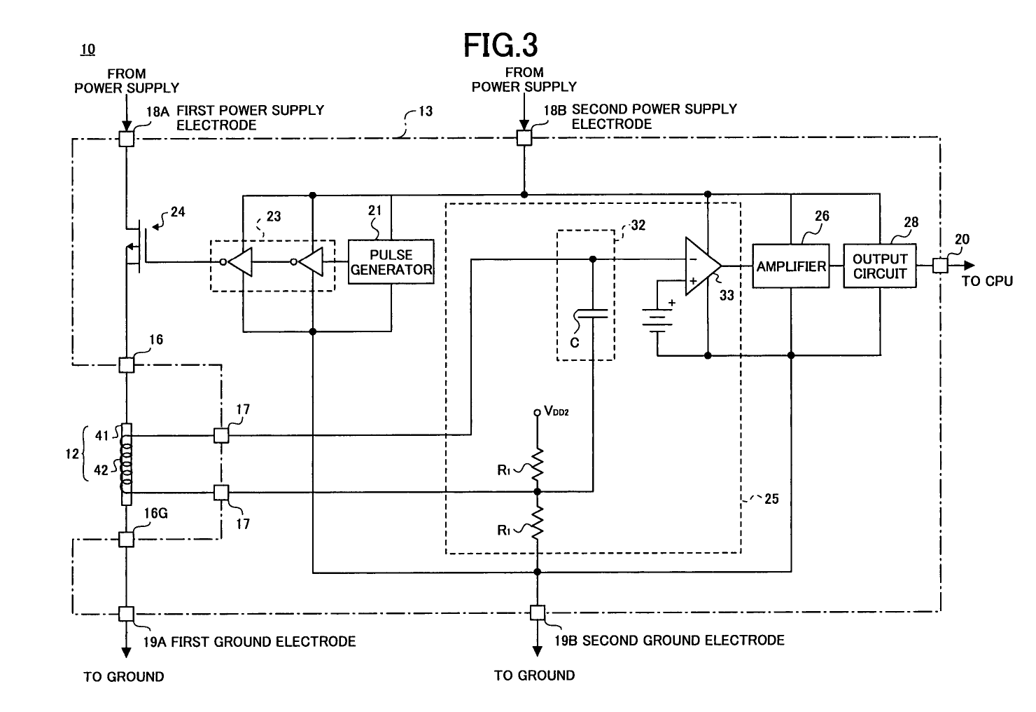

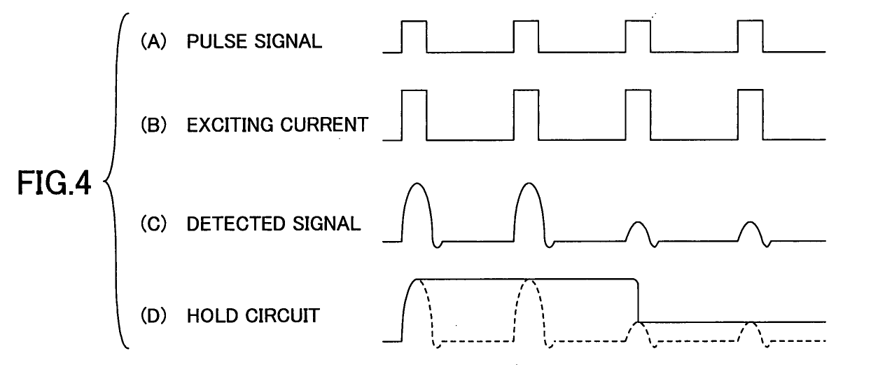

The IC chip 13 of the MI sensor 10 according to the first embodiment is described in detail with reference to FIGS. 3 and 4.

FIG. 3 is a circuit diagram showing the MI sensor 10 according to the first embodiment. FIG. 4 shows waveforms of the MI sensor 10 according to the first embodiment. The IC chip 13 according to the first embodiment includes the following circuits: a pulse generator 21, a buffer circuit 23, a switch circuit 24, a detection circuit 25, an amplifier 26, and an output circuit 28. Each circuit of the IC chip 13 is described in detail below.

Referring to FIG. 3, the pulse generator 21 generates a pulse signal or a high frequency signal of which the frequency is from 200 kHz to several tens MHz. In an embodiment, a pulse signal of 50% duty is generated by a multi-vibrator or a crystal oscillator, for example. The generated pulse signal may be delayed by an integral circuit, for example. The “AND” operation between the generated pulse signal and the inverse signal of the delayed pulse signal results in a pulse signal, as shown in FIG. 4 (A), having a time width between one and 30 nsec. According to the first embodiment, the pulse cycle is set at 500 kHz. The pulse signal generated by the pulse generator 21 is transmitted to the buffer circuit 23.

The buffer circuit 23 includes several to a few several buffers connected in series. The buffer in the down stream may include a CMOS-FET having a greater product of the gate width and the gate length of the CMOS-FET than that of a CMOS-FET included in the buffer in the up stream. Since the greater is the product of the gate width and the gate length of the CMOS-FET, the more drive current the CMOS-FET can provide, the buffer circuit 23 can provide a control unit (not shown) of the switch circuit 24 with greater current.

Referring again to FIG. 3, the pulse signal of which current is amplified by the buffer circuit 23 is input to the control unit of the switch circuit 24. The switch circuit 24 may comprise a MOS-FET, for example, in which case the pulse signal may be input to the gate of the MOS-FET. When the MOS-FET is turned on in response to the pulse signal, the exciting current is provided to the MI element 12 from the MOS-FET via the terminal 16. The exciting current is preferably in the range of 100 mA-500 mA. If the exciting current is less than 100 mA, the voltage induced at the detection coil 42 of the MI element 12 may be too low, in which case the signal to noise ratio may be too low, and consequently, the sensitivity of the MI sensor 10 may be degraded. If the exciting current is more than 500 mA, noise, if any, caused by the switching of the MI element 12 may affect the detection circuit 25, for example, in which case the signal to noise ratio may be degraded.

The power supply line of the switch circuit 24 (top left of FIG. 3) is connected to the first power supply electrode 18A provided on the top face 13a of the IC chip 13 (FIG. 1). The power supply line of the switch circuit 24 is provided independently from the power supply line of the detection circuit 25 and the power supply line of the buffer circuit 23, for example. The power supply line of the switch circuit 24 and the power supply lines of the detection circuit 25 and the buffer circuit 23, for example, are not connected with each other.

The ground line (bottom left of FIG. 3) of the switch circuit 24 is connected to the first ground electrode 19A provided on the top face 13a of the IC chip 13 (FIG. 1). The ground line of the switch circuit 24 is provided independently from the ground line of the detection circuit 25 and the ground line of the buffer circuit 23, for example. The ground line of the switch circuit 24 and the ground lines of the detection circuit 25 and the buffer circuit 23, for example, are not connected with each other. Thus, noise generated by the switching of the switching circuit 24 cannot transmit to the detection circuit 25, for example, via the power supply lines and the ground lines.

The power supply lines of circuits other than the switch circuit 24 are connected to the second power supply electrode 18B (top middle of FIG. 3) provided on the top face 13a of the IC chip 13 (FIG. 1). The ground lines of circuits other than the switch circuit 24 are connected to the second ground electrode 19B (bottom middle of FIG. 3) provided on the top face 13a of the IC chip 13 (FIG. 1). A common external power supply may be connected to and provide power to both the first power supply electrode 18A and the second power supply electrode 18B. In another embodiment, separate external power supplies may be connected to and provide power to the first power supply electrode 18A and the second power supply electrode 18B, respectively. Providing the power supply line of the switch circuit 24 independent from the power supply lines of circuits other than the switch circuit 24 prevents the noise generated by the switch circuit 24 from transmitting to the detection circuit 25, for example.

Referring again to FIG. 3, the exciting current from the switch circuit 24 is transmitted to the MI element 12 via the exciting current electrode 16 (shown in FIG. 1) formed on the top face 13a of the IC chip 13. In an embodiment of the invention, it is desired that the exciting current electrode 16 be disposed as close as possible to both the switch circuit 24 and the MI element 12. The exciting current electrode 16 may be disposed on the top face 13a of the IC chip 13 near the first side face 13b facing the MI element 12. The exciting current is relatively large. If wiring from the switch circuit 24 to the MI element 12 is too long, the wiring radiates electromagnetic waves like an antenna. This radiation may degrade the signal to noise ratio of the MI sensor 10.

The exciting current flows from the exciting current electrode 16 to the ground electrode 16G of the IC chip 13 through the amorphous wire 41 of the MI element 12 shown in FIG. 2. Additionally, the ground electrode 16G is connected to the first ground electrode 19A (bottom left of FIG. 3). As a result, the circuits (the detection circuit 25 and the buffer circuit 23, for example) other than the switch circuit 24 can avoid being affected by the noise generated by the switch circuit 24.

In another embodiment, another ground electrode provided on the case 11 of the MI sensor 10, for example, may be used instead of the ground electrode 16G provided on the IC chip 13. In such case, the exciting current may flow from the MI element 12 through the other ground electrode provided on the case 11 and to a ground provided on a printed circuit board (PCB) on which the MI sensor 10 is mounted.

A detected signal corresponding to the component of the external magnetic field parallel to the amorphous wire 41 is induced at the both ends of the detection coil 42 as shown in FIG. 4 (C). The detected signal is transmitted to the detection circuit 25 via a wiring and the detected signal electrode 17 formed on the top face 13a of the IC chip 13.

The detection circuit 25 includes a hold circuit 32 and an amplifier 33, for example. The hold circuit 32 may comprise a capacitor, for example. As shown in FIG. 4 (D), the peak value of the detected signal is held by the hold circuit 32. The dotted line shown in FIG. 4 (D) denotes the detected signal shown in FIG. 4 (C). The amplifier 33 amplifies the held signal, and outputs the amplified signal as the output signal.

An amplifier 26 amplifies the output signal up to a desired voltage. The amplified output signal is output to an output electrode 20 provided on the top face 13a of the IC chip 13 to an external device such as a CPU. According to the first embodiment, an output circuit 28 is provided to lower the output impedance of the output electrode 20. According to another embodiment, the output circuit 28 may not be provided, and the amplified output signal may be directly output through the output electrode 20. According to yet another embodiment, an analog-to-digital (A/D) converter may be provided, and the output signal may be digitized before output to the output electrode 20. The output signal output from the IC chip 13 is used for determining the amount of external magnetic field by extracting the magnetic field component of the output signal.

In an embodiment of the present invention, the present invention may be characterized by the disposition of circuits constituting the IC chip 13. The disposition of circuits is described below.

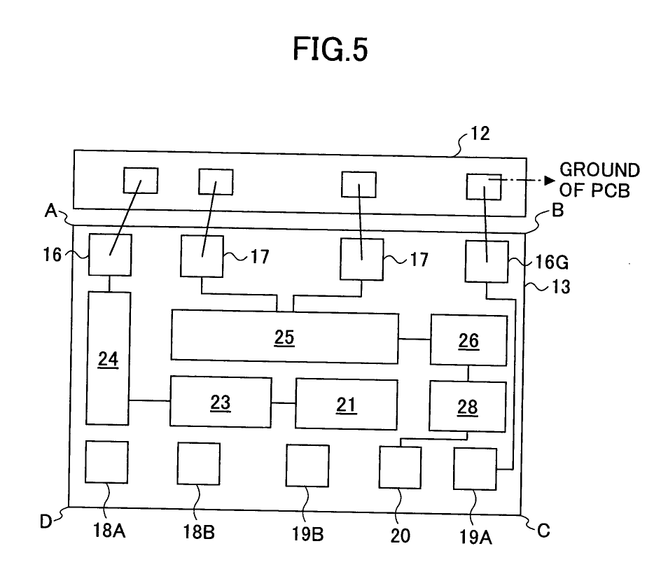

FIG. 5 is a top plan view showing the MI element 12 and the disposition of circuits constituting the IC chip 13 according to the first embodiment. As shown in FIG. 5, the IC chip 13 includes the following: the pulse generator 21, the buffer circuit 23, the switch circuit 24, the detection circuit 25, the amplifier 26, the output circuit 28, the exciting current electrode 16, the exciting current ground electrode 16G, the detection signal electrodes 17, the power supply electrodes 18A, 18B, the ground electrodes 19A, 19B, and the output electrode 20. As described above, in an embodiment of the present invention, the exciting current may be transmitted to the MI element 12 via the exciting current electrode 16 and the exciting current ground electrode 16G. The detected signal from the detection coil of the MI element 12 is input to the detected signal electrodes 17. The voltage of power supply is transmitted to the IC chip 13 via the power supply electrodes 18A and 18B, and the ground electrodes 19A and 19B. The output signal is output via the output electrode 20.

It is noted that the exciting current electrode 16, the exciting current ground electrode 16G, and the detected signal electrodes 17 are disposed near the side face AB (first side face 13b in FIG. 1) facing the MI element 12. It is also noted that the power supply electrodes 18A and 18B, the ground electrodes 19A and 19B, and the output electrode 20 are disposed near the side face CD (second side face 13c in FIG. 1) opposite the side face AB facing the MI element 12.

The first power supply electrode 18A is connected to the switch circuit 24, and the second power supply electrode 18B is connected to the other circuits such as the pulse generator 21, the buffer circuit 23, the detection circuit 25, the amplifier 26, and the output circuit 28. Because the connection between the first power supply electrode 18A and the switch circuit 24 is separate from the connection between the second power supply electrode 18B and the other circuits 21, 23, 25, 26 and 28, for example, noise caused by the exciting current transmitted to the MI element 12 is prevented from affecting the detection circuit 25, for example, through the second power supply electrode 18B and the power supply line connected to the second power supply electrode 18B. Consequently, with such a disposition of the circuits, one can prevent noise from superposing the output signal, for example.

It is further noted that the first power supply electrode 18A, the switch circuit 24, and the exciting current electrode 16 are disposed substantially linearly with respect to one another. Preferably, the first power supply electrode 18A, the switch circuit 24, and the exciting current electrode 16 are disposed with respect to one another so as to be parallel to a side face AD between the side face AB and the side face CD. According to such an arrangement, noise caused by the exciting current is prevented from affecting circuits other than the switch circuit 24. Also, the substantially linear disposition may increase the area efficiency of the IC chip 13, and enable the size of the IC chip 13 to be reduced.

In an embodiment of the present invention, the switch circuit 24 and the exciting current electrode 16 for providing the exciting current to the MI element 12 may be closely disposed in order to make as short as possible the wiring length between the switch circuit 24 and the exciting current electrode 16. According to such an arrangement, the radiation of electromagnetic waves from the wiring may be reduced.

The exciting current electrode 16 is disposed as close as possible to the side face AB (first side face 13b) facing the MI element 12 in order to make as short as possible the wiring length between the exciting current electrode 16 and the MI element 12. According to such an arrangement, the radiation of electromagnetic wave from the wiring is reduced.

The detected signal electrodes 17 and the detection circuit 25 are disposed close to the side face AB (first side face 13b) facing the MI element 12 in order to prevent noise from superposing the detected signal.

An MI sensor provided with one MI element (single axis) has been described. An MI sensor provided with two MI elements (double axes) to which the present invention is applied is described below.

[Second Embodiment]

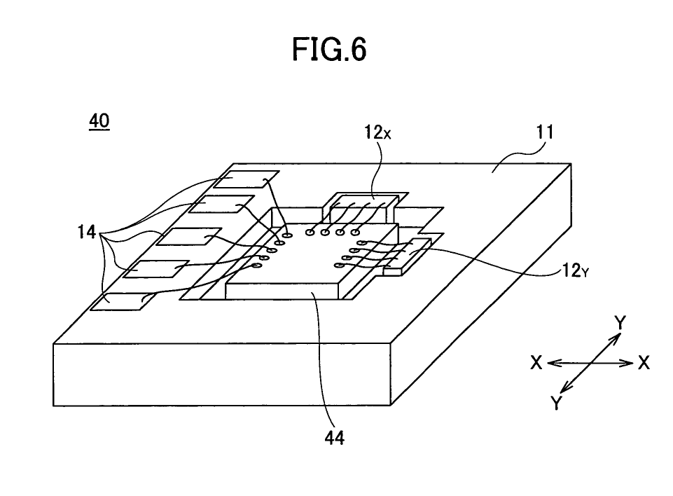

FIG. 6 is a perspective view showing a double axes MI sensor 40 in which two MI elements 12_{X} and 12_{Y} are provided. In FIG. 6, common components are referred to by the same reference numerals and their description is omitted.

Referring to FIG. 6, an MI sensor 40 according to a second embodiment includes a case 11, two MI elements 12_{X} and 12_{Y} disposed in the case 11, and an IC chip 44 disposed in the case 11. The MI elements 12_{X} and 12_{Y} are disposed in a plane, and are perpendicular to each other. The directions in which the MI elements 12_{X} and 12_{Y} are disposed may be referred to as the X axis and the Y axis, respectively. An exemplary manner by which the MI elements 12_{X} and 12_{Y} are connected to the IC chip 44 is described below.

The IC chip 44 provides the MI elements 12_{X} and 12_{Y} with the exciting current. An external magnetic field induces signals on the MI elements 12_{X} and 12_{Y} (magnetic impedance effect). The signals induced on the MI elements 12_{X} and 12_{Y} are detected and processed by the IC chip 44. The detected signals of the MI elements 12_{X} and 12_{Y} depend on the X component and the Y component, respectively, of the external magnetic field. Because the double axes MI sensor 40 can measure the X component and the Y component of the external magnetic field, the direction of the external magnetic field is measurable.

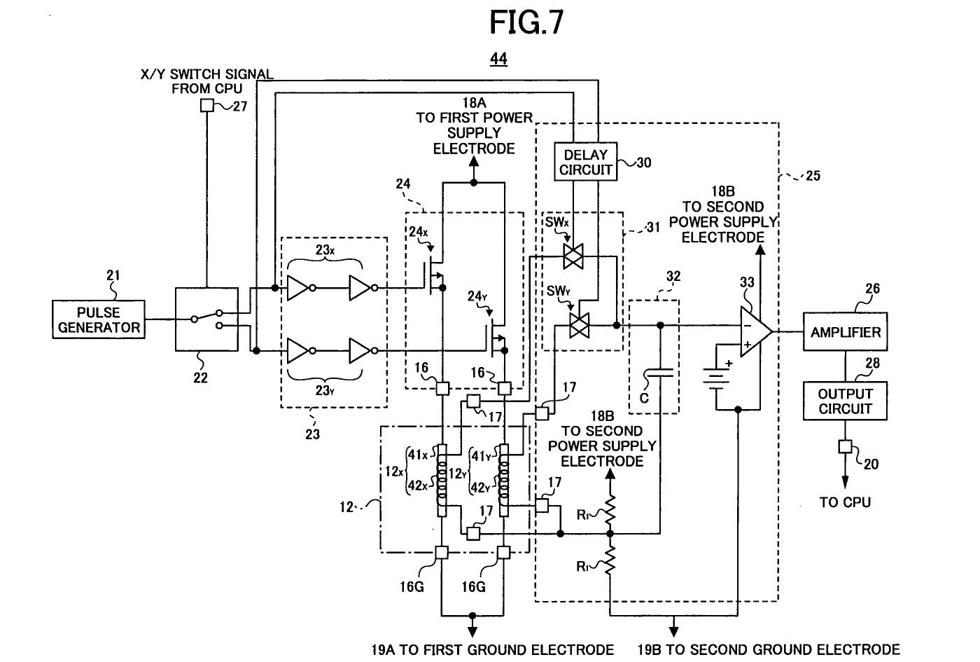

FIG. 7 is a circuit diagram showing the double axes MI sensor 40 according to the second embodiment. Referring to FIG. 7, the IC chip 44 of the MI sensor 40 includes the following: a pulse generator 21, an X/Y axis switch 22, buffer circuits 23_{X} and 23_{Y}, switch circuits 24_{X} and 24_{Y}, a detection circuit 25, an amplifier 26, and an output circuit 28, for example. The IC chip 44 for the double axes MI sensor 40 is the same as the IC chip 13 for the single axis MI sensor 10 shown in FIG. 3, but is different in that the exciting current is transmitted to both MI elements 12_{X} and 12_{Y}, and two circuits are provided in the detection circuit 25 for detecting the signals induced on the MI elements 12_{X} and 12_{Y}.

The buffer circuit 23, switch circuit 24, and sampling circuit 31 (the sampling circuit 31 is described below) of the detection circuit 25, which together constitute a circuit for providing the MI elements 12_{X} and 12_{Y} with the exciting current, are comprised of two independent partial circuits corresponding to the X axis and the Y axis. The other circuits are commonly used for the X axis and the Y axis. Each partial circuit sufficiently provides the respective MI element 12_{X} or 12_{Y} with exciting current. The circuits making up the MI elements 12_{X} and 12_{Y} are separately disposed so that the detected signal of the X axis and the detected signal of the Y axis do not interfere with each other and noise caused by any interference is not increased. The pulse generator 21 generates signals for both the X axis and the Y axis. Likewise, the detection circuit 25 processes signals for both the X axis and the Y axis. Accordingly, the commonly used circuits such as the pulse generator 21 and the detection circuit 25 can avoid difference in sensitivity between the signals for the X axis and the Y axis. Additionally, since some circuits are used in common, the size of the IC chip 44 may be reduced.

The difference between the IC chip 44 of the double axes MI sensor 40 and the IC chip 13 of the single axis MI sensor 10 is described below.

Pulses generated by the pulse generator 21 are transmitted to the X/Y axis switch 22 for switching the generated pulses to the MI elements 12_{X} and 12_{Y}. The X/Y axis switch 22 is controlled by an X/Y switch signal provided from an external source via an X/Y axis switch signal electrode 27. The generated pulse signals are switched to the buffer circuit 23_{X} for the X axis or the buffer circuit 23_{Y} for the Y axis. Specifically, the X/Y switch signal is transmitted by a central processing unit (CPU), for example, to an electronic apparatus in which the double axis MI sensor 40 is provided. The X/Y switch signal is a digital signal indicating either “low” or “high”. For example, when the X/Y axis switch signal is “high”, the generated pulse signals are transmitted to the buffer circuit 23_{X} for the X axis, and otherwise, the generated pulse signals are transmitted to the buffer circuit 23_{Y} for the Y axis.

The switched pulse signals are transmitted to control unit (not shown) of the switch circuits 24_{X} and 24_{Y} via the buffer circuits 23_{X} and 23_{Y}, respectively. The MOS-FETs of the switch circuits 24_{X} and 24_{Y} are turned on in response to the pulse signals, and the exciting current is transmitted to the amorphous wires 41_{X} and 41_{Y} of the respective MI elements 12_{X} and 12_{Y} through the exciting current electrodes 16. Because the pulse signals are transmitted to either one the MI elements 12_{X} or 12_{Y} by the X/Y axis switch 22, the pulse signals are not provided to both MI elements 12_{X} and 12_{Y} simultaneously. This non-simultaneous transmission of the pulse signals to the MI elements 12_{X} and 12_{Y} eliminates crosstalk between the switch circuits 24_{X} and 24_{Y}.

The signals induced on the detection coils 42_{X} and 42_{Y} of the X axis and the Y axis, respectively, are detected by the detection circuit 25, and their main peak values are sampled by the sample circuit 31 in synchronization with the pulse signals and retained by a hold circuit 32.

The sample circuit 31 comprises two analog switches SW_{X} and SW_{Y}. The pulse signal is transmitted from the X/Y axes switch via a delay circuit 30 and is input to a control unit (not shown) of the analog switch SW_{X} (SW_{Y}), for example. When the pulse signal is “high”, the analog switch SW_{X} (SW_{Y}), for example, transmits the signal induced on the detection coil 42_{X} (42_{Y}). Compared with the pulse signal, the detected signal is delayed due to the buffer circuit 23 and the switch circuit 24, for example. Because the pulse signal is synchronized with the detected signal, the sample circuit 31 can transmit the main peak of the detected signal.

The hold circuit 32 retains the peak value of the detected signal. The retained peak value is output through the amplifier 26 and the output circuit 28 in the same manner as the IC chip 13 of the single axis MI sensor 10.

In an embodiment of the present invention, the IC chip 44 for the double axes MI sensor 40 may be characterized in that both the power supply line and the ground line of the switching circuit 24_{X} (24_{Y}) are provided independently from the power supply lines and the ground lines of other circuits such as the detection circuit 25. The power supply line and the ground line of the switching circuit 24_{X} (24_{Y}) are not electrically connected to the power supply lines and the ground lines, respectively, of the other circuits. Accordingly, noise generated by the switch circuit 24 is prevented from affecting the detection circuit 25, for example, through the power supply line and the ground line in the same manner as the IC chip 13 of the single axis MI sensor 10.

[Third Embodiment]

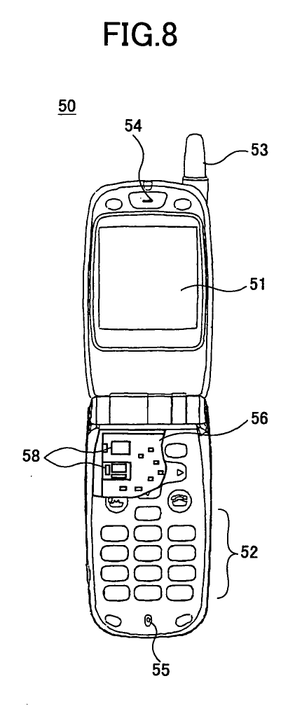

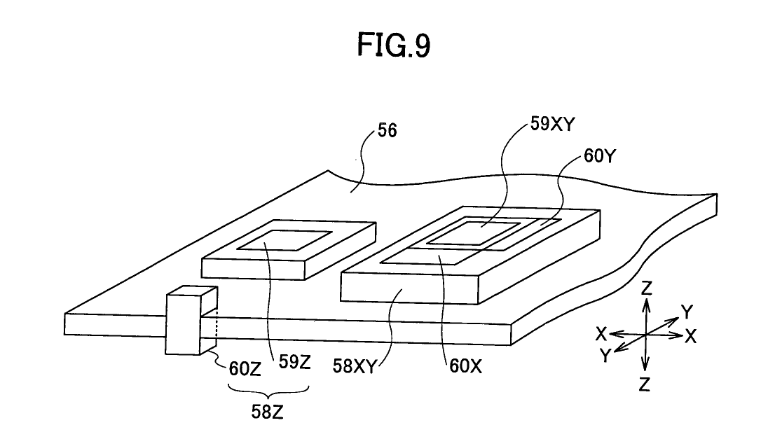

FIG. 8 is an exploded view of a cellular phone 50 according to a third embodiment. FIG. 9 is an enlarged view showing the a portion of the cellular phone 50 where MI sensors according to an embodiment of the present invention are disposed.

Referring to FIGS. 8 and 9, the cellular phone 50 includes the following: a display unit 51, an operations unit 52, an antenna 53, a speaker 54, a microphone 55, a communication board 56, and MI sensors 58 provided on the communication board 56.

An MI sensor 58_{Z} (FIG. 9) is structured in the same manner as the single axis MI sensor 10 according to the first embodiment. The MI sensor 58_{Z} includes an IC chip 59_{Z} and an MI element 60_{Z}. The IC chip 59_{Z} and the MI element 60_{Z} are disposed separately. To reduce the height of the communication board 56, the MI element 60_{Z} is plugged into a recess, or notch, in the communication board 56.

The other MI sensor 58_{XY} is structured in the same manner as the double axis MI sensor 40 according to the second embodiment. The MI sensor 58_{XY} is provided with an IC chip 59_{XY} and MI elements 60_{X} and 60_{Y}.

The double axes MI sensor 58_{XY} detects a magnetic field in the plane of the communication board 56. The directions corresponding to the MI elements 60_{X} and 60_{Y} are referred to as the X axis and the Y axis, respectively. The single axis MI sensor 58_{Z} detects a magnetic field perpendicular to the plane of the communication board 56. The direction corresponding to the MI element 60Z is referred to as the Z axis. The direction of the cellular phone 50 can be determined by detecting the earth's magnetism. For example, when the cellular phone 50 is positioned substantially vertically facing either north or south, that is, when the Z axis of the communication board 56 lies in the north-south direction, the magnetic field of the X axis and the Y axis becomes substantially zero.

The direction of the cellular phone 50 can be determined as described above. If the cellular phone 50 has a map around the current position of the cellular phone 50, it can display the map on the display unit 51 to the determined direction so that a user of the cellular phone 50 can easily read the map.

According to another embodiment, a combination of three single axis MI sensors may be used instead of the combination of the single axis MI sensor 58_{Z} and the double axes MI sensor 58_{XY}.

In the case of the MI sensors 58_{XY} and 58_{Z} according to the third embodiment, the external magnetic field can be detected by driving the MI elements 60_{XY} and 60_{Z} by the IC chips 59_{XY} and 59_{Z}. Since the electronic circuits for driving the MI elements 60_{XY} and 60_{Z} are integrated in the IC chips 59_{XY} and 59_{Z}, the MI sensors 58_{XY} and 58_{Z} can be downsized.

The cellular phone 50 according to the third embodiment has been described above. The present invention is, however, applicable to any electronic apparatus such as a mobile terminal and/or a car navigation system.

In summary, according to the present invention, a compact highly sensitive MI sensor, an IC chip for the MI sensor, and an electronic apparatus into which the MI sensor may be built can be provided.

The preferred embodiments of the present invention are described above. The present invention is not limited to these embodiments, but variations and modifications may be made without departing from the scope of the present invention.

This patent application is based on Japanese Priority Patent Application No. 2002-318249 filed on Oct. 31, 2002, the entire contents of which are hereby incorporated by reference.

What is claimed is:

1. An IC chip for providing an exciting current to an MI element of an MI sensor, which MI element detects an external magnetic field, the MI chip comprising:
an MI element electrode to which the MI element is connected;
a switch unit that, in response to a pulse signal, provides the MI element with the exciting current via said MI element electrode; and
a first power supply electrode through which said switch unit is provided with electric power;
the IC chip having a first side face and a second side face opposite the first side face;
wherein
said MI element electrode is disposed in a neighborhood of the first side face; and
said first power supply electrode is disposed in a neighborhood of the second side face.

2. The IC chip as claimed in claim 1, wherein said MI element electrode, said switch unit, and said first power supply electrode are disposed substantially linearly.

3. The IC chip as claimed in claim 1, further comprising:
a detected signal electrode to which a detected signal is provided from the MI element;
a signal processing unit that receives the detected signal via said detected signal electrode and processes the received detected signal; and
a second power supply electrode through which said signal processing unit is provided with electric power;
wherein
said detected signal electrode is disposed in a neighborhood of the first side face; and
said second power supply electrode is disposed in a neighborhood of the second side face.

4. The IC chip as claimed in claim 3, wherein the electric power is provided to said switch unit and said signal processing unit through different power supply wirings.

5. The IC chip as claimed in claim 3, wherein said switch unit and said signal processing unit are connected to different ground lines.

6. An IC chip for providing via an MI element electrode an exciting current to an MI element of an MI sensor, the IC chip comprising:
a switch unit that, in response to a pulse signal, provides the MI element with the exciting current via the MI element electrode; and
a signal processing unit that receives a detected signal from the MI element and processes the received detected signal;
wherein
electric power is provided to said switch unit and said signal processing unit through different power supply wirings.

7. The IC chip as claimed in claim 6, wherein said switch unit and said signal processing unit are connected to different ground lines.

8. An MI sensor, comprising:
an MI element for detecting an external magnetic field; and
an IC chip for providing an exciting current to the MI element;
wherein
said IC chip comprises:
an MI element electrode to which the MI element is connected;
a switch unit that, in response to a pulse signal, provides said MI element with the exciting current via said MI element electrode; and
a first power supply electrode through which said switch unit is provided with electric power;
wherein said IC chip has a first side face and a second side face opposite the first side face; and
wherein
said MI element electrode is disposed in a neighborhood of the first side face; and
said first power supply electrode is disposed in a neighborhood of the second side face.

9. The MI sensor as claimed in claim 8, wherein said MI element electrode, said switch unit, and said first power supply electrode are disposed substantially linearly.

10. The MI sensor as claimed in claim 8, wherein
said IC chip further comprises:
a detected signal electrode to which a detected signal is provided from said MI element;
a signal processing unit that receives the detected signal via said detected signal electrode and processes the received detected signal; and
a second power supply electrode through which said signal processing unit is provided with the electric power;
wherein
said detected signal electrode is disposed in a neighborhood of the first side face; and
said second power supply electrode is disposed in a neighborhood of the second side face.

11. The MI sensor as claimed in claim 10, wherein the electric power is provided to said switch unit and said signal processing unit through different power supply wirings.

12. The MI sensor as claimed in claim 10, wherein said switch unit and said signal processing unit are connected to different ground lines.

13. An MI sensor, comprising:
an MI element; and
an IC chip for providing an exciting current to the MI element via an MI element electrode;
wherein said IC chip comprises:
a switch unit that, in response to a pulse signal, provides the MI element with the exciting current via the MI element electrode; and
a signal processing unit that receives a detected signal from said MI element and processes the received detected signal; and
electric power is provided to said switch unit and said signal processing unit through different power supply wirings.

14. The MI sensor as claimed in claim 13, wherein said switch unit and said signal processing unit are connected to different ground lines.

15. An electronic apparatus into which said MI sensor as claimed in claim 8 is built.
